(19) United States
(12) Patent Application Publication
(10) Pub. No.: US 2026/0114044 A1
(43) Pub. Date: Apr. 23, 2026

(54) SEMICONDUCTOR DEVICE AND METHOD OF FABRICATING THE SAME

(71) Applicant: Samsung Electronics Co., Ltd., Suwon-si (KR)

(72) Inventors: Uk HYEON, Suwon-si (KR); Youngwoong KIM, Suwon-si (KR); MOON GI CHO, Suwon-si (KR); HWASUNG RHEE, Suwon-si (KR); HOCHUL LIM, Suwon-si (KR)

(21) Appl. No.: 19/193,201

(22) Filed: Apr. 29, 2025

(30) Foreign Application Priority Data
Oct. 21, 2024 (KR) 10-2024-0144278

(51) Int. Cl. H10D 84/90; H10D 89/10

(52) U.S. Cl. CPC H10D 84/966; H10D 84/951; H10D 89/10

(57) ABSTRACT

A method of fabricating a semiconductor device may include providing a substrate, forming active fin regions, source/drain patterns, gate structures, and an inter-gate insulating layer on the substrate, forming full height contacts, forming full height gate contacts, recessing a first subset of the full height contacts and a second subset of the full height gate contacts to form reduced height contacts and reduced height gate contacts, respectively, forming an upper insulating pattern, and forming interconnection patterns on the full height contacts, the full height gate contacts, and the upper insulating pattern.

### CROSS-REFERENCE TO RELATED APPLICATIONS

This U.S. non-provisional patent application claims priority under 35 U.S.C. § 119 to Korean Patent Application No. 10-2024-0144278, filed on Oct. 21, 2024, in the Korean Intellectual Property Office, the entire contents of which are hereby incorporated by reference.

### BACKGROUND OF THE INVENTION

The present disclosure relates to a semiconductor device and a method of fabricating the same, and in particular, to a semiconductor device including a field effect transistor.

A semiconductor device includes an integrated circuit consisting of metal-oxide-semiconductor field-effect transistors (MOS-FETs). To meet an increasing demand for the semiconductor device with a small pattern size and a reduced design rule, the MOS-FETs are being scaled down in size. The scale-down of the MOS-FETs may lead to deterioration in operation characteristics of the semiconductor device. Accordingly, a variety of studies are being conducted to overcome technical limitations associated with the scale-down of the semiconductor device and to provide a high performance semiconductor device.

### SUMMARY

An embodiment of the inventive concept provides a semiconductor device with improved reliability.

An embodiment of the inventive concept provides a semiconductor device with improved electrical characteristics.

According to an embodiment of the inventive concept, a method of fabricating a semiconductor device may include providing a, forming active fin regions, source/drain patterns, gate structures, and an inter-gate insulating layer on the substrate, forming full height contacts penetrating through the inter-gate insulating layer and that are respectively connected to the source/drain patterns, forming full height gate contacts respectively connected to the gate structures, recessing a first subset of the full height contacts and a second subset of the full height gate contacts to form reduced height contacts and reduced height gate contacts, respectively, forming an upper insulating pattern on the reduced height contacts and the reduced height gate contacts, and forming interconnection patterns on the full height contacts, the full height gate contacts, and the upper insulating pattern.

According to an embodiment of the inventive concept, a method of fabricating a semiconductor device may include providing a substrate, forming active fin regions, source/drain patterns, gate structures, and an inter-gate insulating layer on the substrate, forming full height contacts penetrating through the inter-gate insulating layer that are respectively connected to the source/drain patterns, the full height contacts each including a corresponding full height barrier pattern, forming a full height gate contacts respectively connected to the gate structures, the full height gate contacts each including a full height gate barrier pattern, simultaneously recessing a first subset of the full height contacts and a second subset of the full height gate contacts to form reduced height contacts and reduced height gate contacts, and forming an upper insulating pattern on the reduced height contacts and the reduced height gate contacts. The forming of the reduced height contacts and the reduced height gate contacts may include removing a portion of the full height barrier patterns of the first subset of the full height contacts and a portion of the full height gate barrier patterns of the second subset of full height gate contacts simultaneously.

According to an embodiment of the inventive concept, a method of fabricating a semiconductor device may include providing a substrate, forming active fin regions on the substrate, forming gate structures on the active fin regions, forming first source/drain patterns and second source/drain patterns on the first and second active regions of the substrate, respectively, forming an inter-gate insulating layer to cover the first source/drain patterns and the second source/drain patterns, forming full height contacts respectively connected to the first source/drain patterns and penetrating through the inter-gate insulating layer, forming full height gate contacts respectively connected to the gate structures, recessing a first subset of the full height contacts to form reduced height contacts, recessing a second subset of the full height gate contacts to form reduced height gate contacts, forming an upper insulating pattern on the reduced height contacts and the reduced height gate contacts, and forming interconnection patterns on the full height contacts, the full height gate contacts, and the upper insulating pattern. The recessing of the first subset of full height contacts and the recessing of the second subset of full height gate contacts may be performed simultaneously, and the forming of the interconnection patterns may include forming the interconnection patterns spaced apart from each other in a first direction parallel to the substrate and having a line shape extending in a second direction crossing the first direction.

### BRIEF DESCRIPTION OF THE DRAWINGS

FIGS. 1 to 3 are conceptual diagrams illustrating logic cells of a semiconductor device according to an embodiment of the inventive concept.

FIG. 4 is a plan view illustrating a semiconductor device according to an embodiment of the inventive concept.

FIGS. 5A to 5D are sectional views respectively taken along lines A-A′, B-B′, C-C′, and D-D′ of FIG. 4.

FIG. 5E is a sectional view illustrating a semiconductor device according to an embodiment of the inventive concept and corresponding to the line C-C′ of FIG. 4.

FIGS. 6A, 7A, 8A, 9A, 10A, and 11A are sectional views, which are taken along the line B-B′ of FIG. 4 to illustrate a method of fabricating a semiconductor device, according to an embodiment of the inventive concept.

FIGS. 6B, 7B, 8B, 9B, 10B, and 11B are sectional views, which are taken along the line D-D′ of FIG. 4 to illustrate a method of fabricating a semiconductor device according to an embodiment of the inventive concept.

### DETAILED DESCRIPTION

Example embodiments of the inventive concepts will now be described more fully with reference to the accompanying drawings, in which example embodiments are shown. The inventive concept may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate and layers formed on the base substrate.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

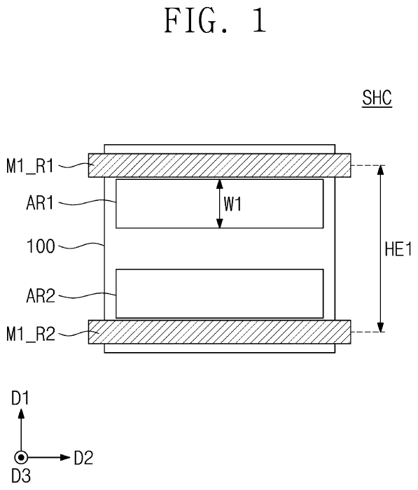

FIGS. 1 to 3 are conceptual diagrams illustrating logic cells of a semiconductor device according to an embodiment of the inventive concept. Like all the semiconductor devices disclosed herein, the semiconductor memory device may be a semiconductor chip. Such a semiconductor chip may be a semiconductor device singulated from (e.g., cut from) a wafer (which wafer may be formed with one base substrate (e.g., a bulk silicon substrate, a bulk germanium substrate, silicon on insulator (SOI), etc.), e.g., or formed with a combination of several component wafers each having a corresponding base substrate).

Referring to FIG. 1, a single height cell SHC may be provided. For example, a first power line M1_R1 and a second power line M1_R2 may be provided on a substrate 100. The first power line M1_R1 may be a conduction path to which a source voltage VSS (e.g., a ground voltage) is provided. The second power line M1_R2 may be a conduction path to which a drain voltage VDD (e.g., a power voltage) is provided.

The single height cell SHC may be defined between the first power line M1_R1 and the second power line M1_R2. The single height cell SHC may include a first active region AR1 and a second active region AR2. One of the first and second active regions AR1 and AR2 may be a PMOSFET region, and the other of the first and second active regions AR1 and AR2 may be an NMOSFET region. For example, the single height cell SHC may have a CMOS structure provided between the first power line M1_R1 and the second power line M1_R2.

Each of the first and second active regions AR1 and AR2 may have a first width W1 in a first direction D1. A length of the single height cell SHC in the first direction D1 may be defined as a first height HE1. The first height HE1 may be equal or substantially equal to a distance (e.g., a pitch) between the first and second power lines M1_R1 and M1_R2.

The single height cell SHC may constitute a single logic cell. In the present disclosure, the logic cell may be a logic device (e.g., AND, OR, XOR, XNOR, inverter, and so forth), which is configured to execute a specific function. For example, the logic cell may include transistors constituting the logic device and interconnection lines connecting the transistors to each other.

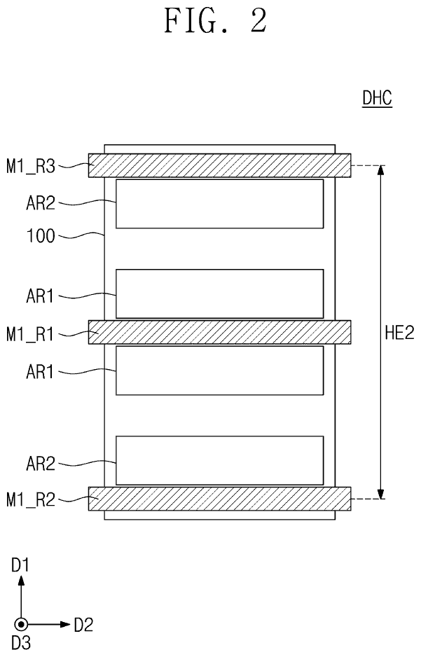

Referring to FIG. 2, a double height cell DHC may be provided. For example, a first power line M1_R1, a second power line M1_R2, and a third power line M1_R3 may be provided on the substrate 100. The first power line M1_R1 may be disposed between the second power line M1_R2 and the third power line M1_R3. The third power line M1_R3 may be a conduction path to which the source voltage VSS is provided.

The double height cell DHC may be defined between the second power line M1_R2 and the third power line M1_R3. The double height cell DHC may include a pair of first active regions AR1 and a pair of second active regions AR2.

One of the pair of the second active regions AR2 may be adjacent to the second power line M1_R2. The other of the second active regions AR2 may be adjacent to the third power line M1_R3. The pair of the first active regions AR1 may be adjacent to the first power line M1_R1. When viewed in a plan view, the first power line M1_R1 may be disposed between the pair of the first active regions AR1.

A length of the double height cell DHC in the first direction D1 may be defined as a second height HE2. The second height HE2 may be two times or about two times the first height HE1 of FIG. 1. The pair of the first active regions AR1 of the double height cell DHC may be combined to serve as a single active region.

In an embodiment, the double height cell DHC of FIG. 2 may be defined as a multi-height cell. Although not shown, the multi-height cell may include a triple height cell whose cell height is about three times that of the single height cell SHC.

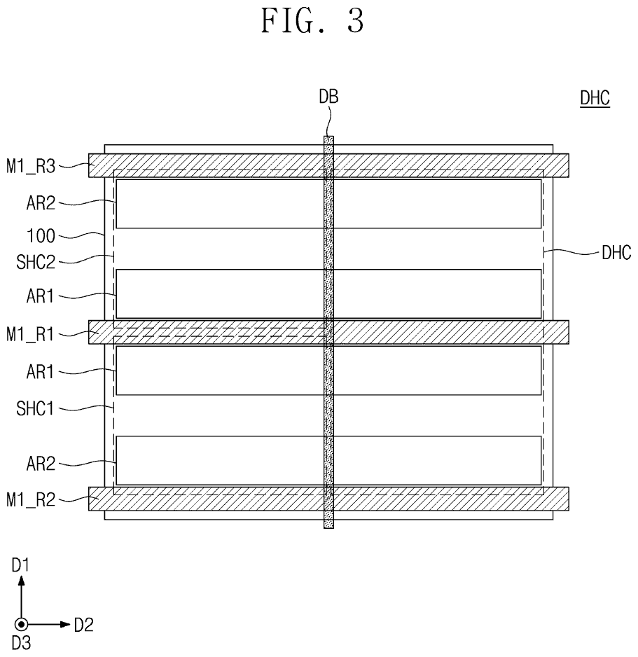

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

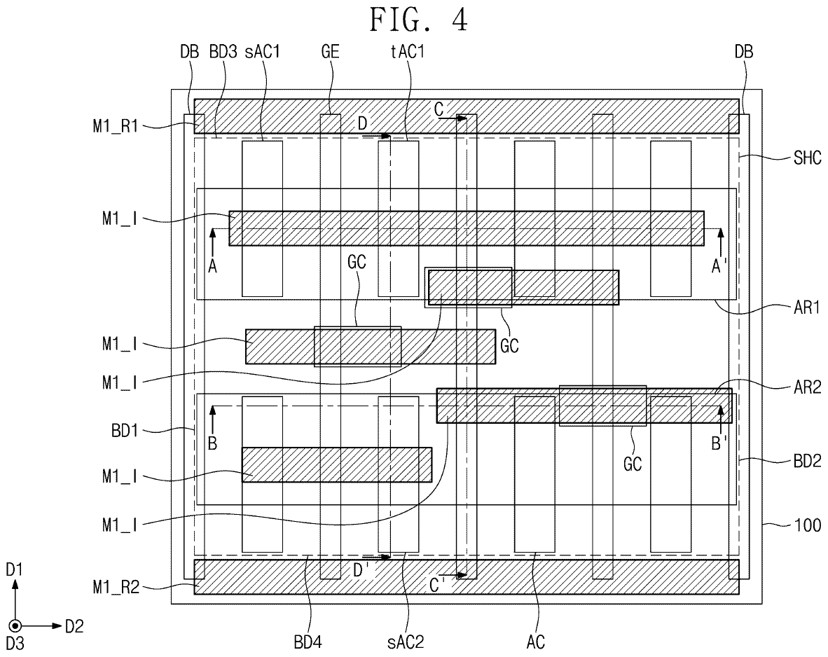

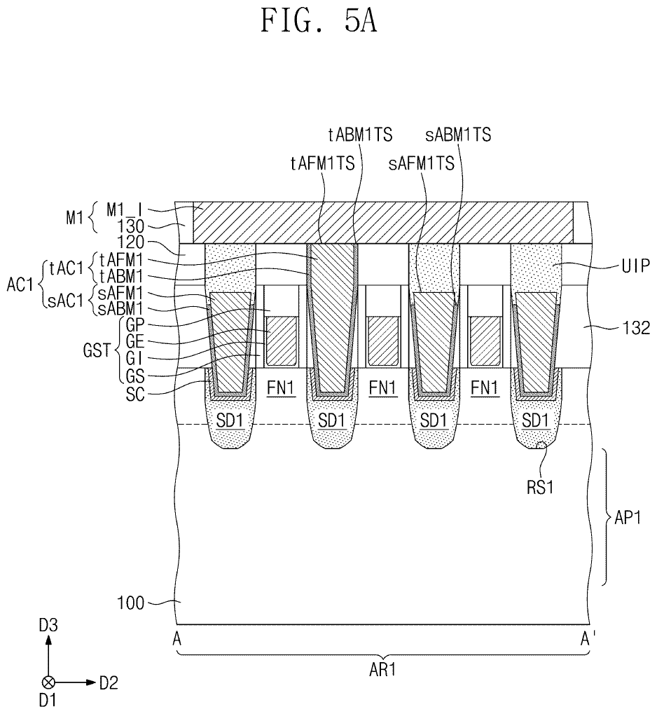

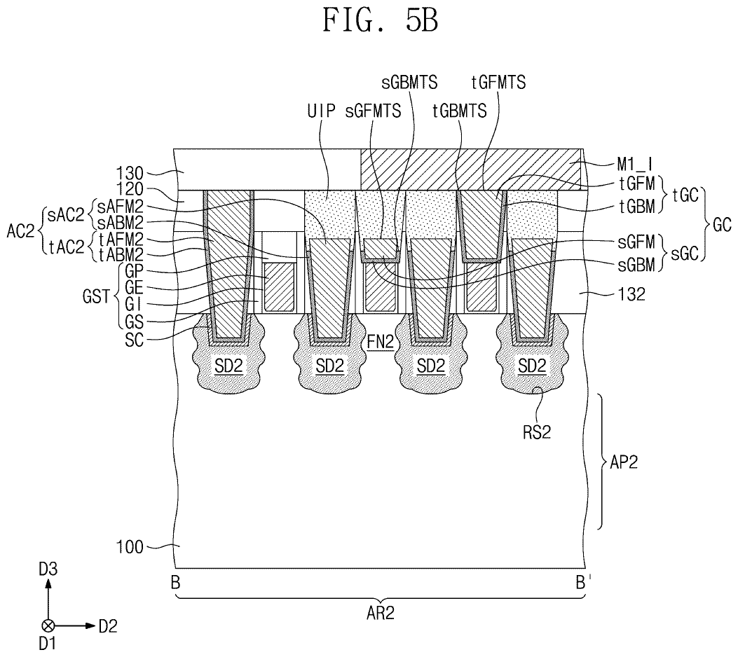

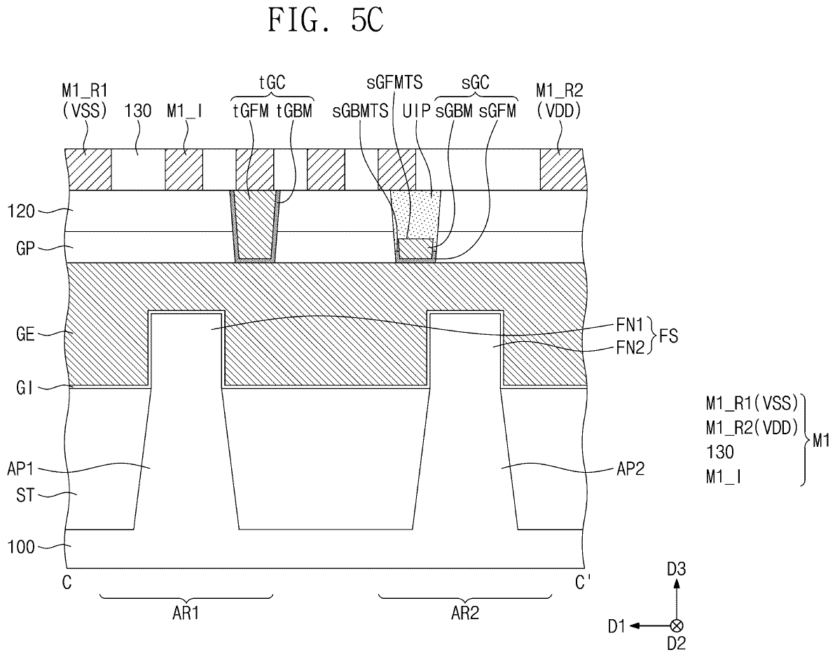

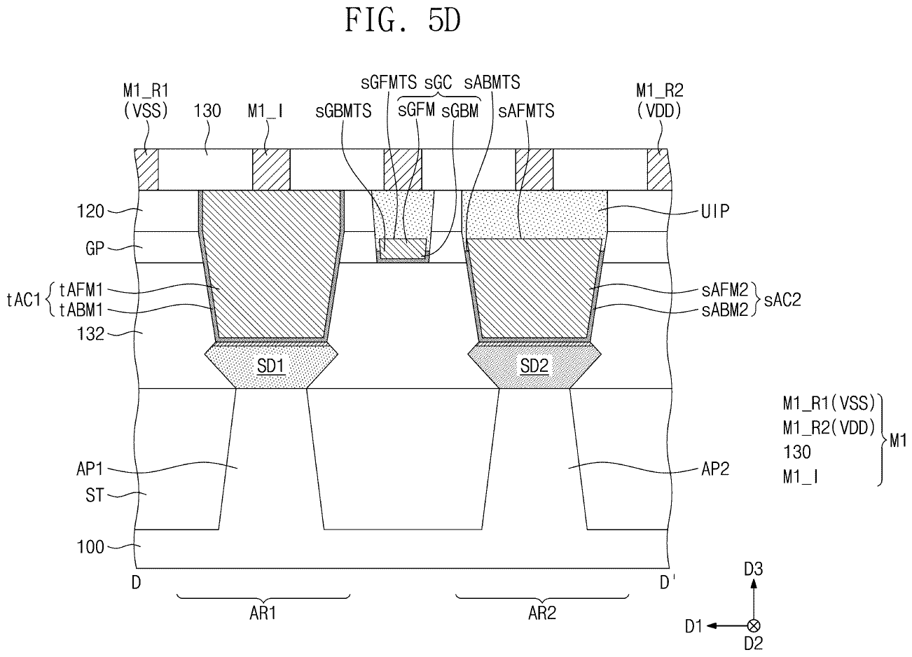

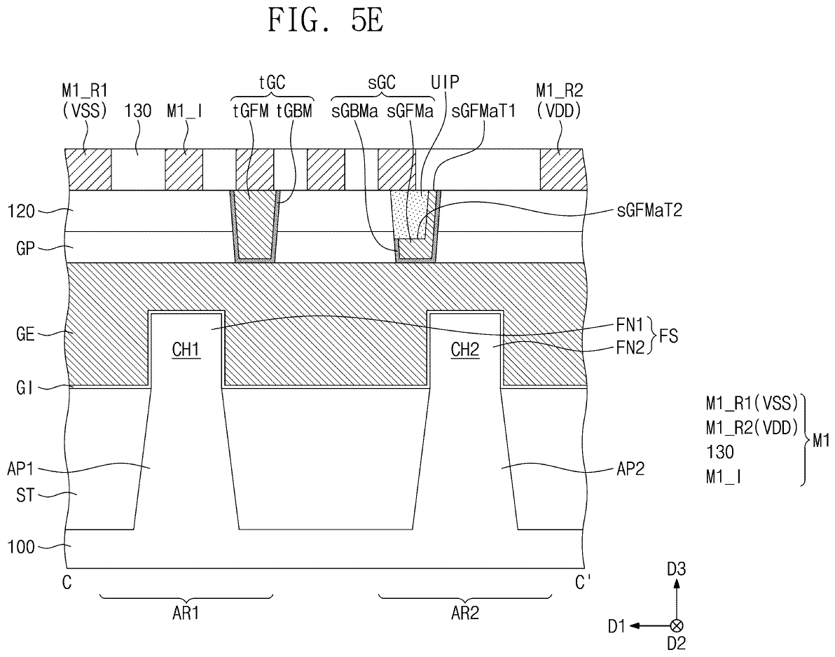

FIG. 4 is a plan view illustrating a semiconductor device according to an embodiment of the inventive concept. FIGS. 5A to 5D are sectional views taken along lines A-A′, B-B′, C-C′, and D-D′ of FIG. 4. The semiconductor device of FIGS. 4 and 5A to 5D may be an example of the single height cell SHC of FIG. 1.

Referring to FIGS. 4 and 5A to 5D, the single height cell SHC may be provided on the substrate 100. Logic transistors constituting a logic circuit may be disposed on the single height cell SHC. The substrate 100 may be a semiconductor substrate that is formed of and/or includes silicon, germanium, silicon germanium, or a compound semiconductor material. In an embodiment, the substrate 100 may be a silicon substrate.

The single height cell SHC may have a first border BD1 and a second border BD2, which are opposite to each other in the second direction D2. The first and second borders BD1 and BD2 may extend in the first direction D1. The single height cell SHC may have a third border BD3 and a fourth border BD4, which are opposite to each other in the first direction D1. The third and fourth borders BD3 and BD4 may extend in the second direction D2.

A pair of division structures DB, which are opposite to each other in the second direction D2, may be provided at opposite sides of the single height cell SHC. For example, a pair of division structures DB may be provided on the first and second borders BD1 and BD2 of the single height cell SHC, respectively. The division structure DB may extend lengthwise in the first direction D1 to be parallel to a gate electrodes GE. A pitch between the division structure DB and the gate electrode GE adjacent thereto may be equal to the first pitch.

The substrate 100 may include the first active region AR1 and the second active region AR2. Each of the first and second active regions AR1 and AR2 may extend in the second direction D2.

A first active pattern AP1 and a second active pattern AP2 may be defined by a trench formed in an upper portion of the substrate 100 (e.g., the first active pattern AP1 and the second active pattern AP2 may each be surrounded by the trench formed in the upper portion of the substrate). The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be vertically protruding portions of the substrate 100.

The first and second active patterns AP1 and AP2, which protrude above a device isolation layer ST, may form a first active fin region FN1 and a second active fin region FN2. The first and second active fin regions FN1 and FN2 may be active fin regions FS. The first active fin region FN1 may be provided on the first active pattern AP1. The second active fin region FN2 may be provided on the second active pattern AP2.

The first and second active patterns AP1 and AP2 may be disposed to neighbor each other in the first direction D1 parallel to a bottom surface of the substrate 100. Each of the first and second active patterns AP1 and AP2 may extend in the second direction D2, which is parallel to the bottom surface of the substrate 100 and is not parallel (e.g., is orthogonal) to the first direction D1. Each of the first and second active patterns AP1 and AP2 may protrude upward from the substrate 100 in a third direction D3 that is perpendicular to the first and second directions D1 and D2.

The device isolation layer ST may be provided on the substrate 100. The device isolation layer ST may be provided to fill a region between the first and second active patterns AP1 and AP2, which are spaced apart from each other. The device isolation layer ST may not cover the active fin regions FS (e.g., may have an upper surface below an upper surface of the active fin regions FS).

A plurality of first source/drain patterns SD1 may be provided on the first active pattern AP1. The first source/drain patterns SD1 may be provided in first recesses RS1 formed in the first active fin region FN1, respectively. The first source/drain patterns SD1 may be impurity regions of a first conductivity type (e.g., p-type). A channel pattern may be interposed between a pair of the first source/drain patterns SD1. The first active fin region FN1, which is interposed between the pair of the first source/drain patterns SD1, may serve as a channel region.

A plurality of second source/drain patterns SD2 may be provided on the second active pattern AP2. The second source/drain patterns SD2 may be provided in second recesses RS2 formed in the second active fin region FN2, respectively. The second source/drain patterns SD2 may be impurity regions of a second conductivity type (e.g., n-type), which may be different than the first conductivity type. A channel pattern may be interposed between a pair of the second source/drain patterns SD2. The second active fin region FN2, which is interposed between the pair of the second source/drain patterns SD2, may serve as a channel region.

The first and second source/drain patterns SD1 and SD2 may be spaced apart from each other in the first and second directions D1 and D2.

The active fin regions FS may be interposed between the source/drain patterns SD1 and SD2. The source/drain patterns SD1 and SD2 may cover side surfaces of the active fin regions FS, and bottom surfaces of the source/drain patterns SD1 and SD2 may be located at a height lower than top surfaces of the active fin regions FS.

The source/drain patterns SD1 and SD2 may be epitaxial patterns, which are formed by a selective epitaxial growth (SEG) process. The source/drain patterns SD1 and D2 may be epitaxially-grown patterns, which are formed of at least one of silicon germanium (SiGe), silicon (Si), or silicon carbide (SiC).

In an embodiment, the first source/drain patterns SD1 may be formed of and/or include a semiconductor material (e.g., SiGe) whose lattice constant is greater than that of a semiconductor material of the substrate 100. Thus, a pair of the first source/drain patterns SD1 may exert a compressive strain to a channel pattern (i.e., the first active fin region FN1) therebetween.

The second source/drain patterns SD2 may be formed of and/or include the same semiconductor element (e.g., Si) as the substrate 100. Thus, the pair of the second source/drain patterns SD2 may exert a tensile strain to a channel pattern (i.e., the second active fin region FN2) therebetween.

In an embodiment, the second source/drain pattern SD2 may have an uneven or embossed side surface. For example, the side surface of the second source/drain pattern SD2 may have a wavy or jagged profile. The side surface of the second source/drain pattern SD2 may portions that protrude toward the second active fin region FN2.

A gate structure GST may be provided on the first and second active fin regions FN1 and FN2. The gate structure GST may include a gate insulating pattern GI, a gate electrode GE on the gate insulating pattern GI, a gate capping pattern GP on the gate electrode GE, and a gate spacer GS in contact with the gate insulating pattern GI and the gate capping pattern GP.

The gate insulating pattern GI may conformally cover the exposed top surface of the device isolation layer ST and the exposed top and side surfaces of the first and second active fin regions FN1 and FN2. The gate insulating pattern GI may be formed of and/or include at least one of silicon oxide or high-k dielectric materials (e.g., HfO₂, HfSiO, HfSiON, HfON, HfAlO, HfLaO, and TaO₂).

The gate electrode GE may be provided on the gate insulating pattern GI. In an embodiment, a plurality of gate electrodes GE may be provided. The gate insulating pattern GI may be interposed between the gate electrode GE and the first and second active fin regions FN1 and FN2. The gate electrode GE may be formed of and/or include a conductive material and may be formed of and/or include at least one of conductive metal nitride materials (e.g., titanium nitride tantalum nitride) or metallic materials (e.g., aluminum or tungsten).

Each of the gate electrodes GE may extend lengthwise in the first direction D1. Each of the gate electrodes GE may vertically overlap with the first and second active fin regions FN1 and FN2. The gate electrodes GE may be arranged to be spaced apart from one another in the second direction D2 at a first pitch. The gate electrodes GE may extend lengthwise in the first direction D1 and may be arranged spaced apart from one another in the second direction D2, which is not parallel to the first direction D1.

The gate capping pattern GP may be disposed on the gate electrode GE. The gate capping pattern GP may cover a top surface of the gate electrode GE and may extend in the first direction D1. The gate capping pattern GP may include a material having an etch selectivity with respect to a first interlayer insulating layer 120 to be described below. The gate capping pattern GP may be formed of and/or include at least one of SiON, SiCN, SiCON, or SiN.

The gate spacer GS may be disposed on opposite side surfaces of the gate electrode GE and opposite side surfaces of the gate capping pattern GP. The gate spacer GS may extend in an extension direction of the gate electrode GE, on the opposite side surfaces of the gate electrode GE. The gate insulating pattern GI may be interposed between the gate electrode GE and the gate spacer GS. In an embodiment, the gate spacer GS may be formed of and/or include at least one of silicon oxide, silicon nitride, silicon oxynitride, silicon carbon nitride, or combinations thereof.

An inter-gate insulating layer 132 may be disposed between adjacent ones of the gate structure GST to cover the first and second source/drain patterns SD1 and SD2. The inter-gate insulating layer 132 may be formed of and/or include at least one of silicon nitride, silicon oxide, or silicon oxynitride.

In an embodiment, the gate insulating layer GI may include a silicon oxide layer, a silicon oxynitride layer, and/or a high-k dielectric layer. For example, the gate insulating layer GI may have a structure in which a silicon oxide layer and a high-k dielectric layer are stacked. The high-k dielectric layer may be formed of and/or include a high-k dielectric materials whose dielectric constant is higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In an embodiment, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. In contrast, in the case where at least one of serially-connected capacitors has a negative capacitance, a total capacitance of the serially-connected capacitors may have a positive value and may be greater than an absolute value of the capacitance of each of the capacitors.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS) that is less than 60 mV/decade at room temperature.

The ferroelectric layer may have the ferroelectric property. The ferroelectric layer may be formed of and/or include at least one of, for example, hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. The dopants may include at least one of, for example, aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, for example, gadolinium (Gd), silicon (Si), zirconium (Zr), aluminum (Al), and/or yttrium (Y).

In the case where the dopants are aluminum (Al), a content of aluminum in the ferroelectric layer may range from 3 to 8 at % (atomic percentage). Here, the content of the dopants (e.g., aluminum atoms) may be a ratio of the number of aluminum atoms to the total number of hafnium and aluminum atoms.

In the case where the dopants are silicon (Si), a content of silicon in the ferroelectric layer may range from 2 at % to 10 at %. In the case where the dopants are yttrium (Y), a content of yttrium in the ferroelectric layer may range from 2 at % to 10 at %. In the case where the dopants are gadolinium (Gd), a content of gadolinium in the ferroelectric layer may range from 1 at % to 7 at %. In the case where the dopants are zirconium (Zr), a content of zirconium in the ferroelectric layer may range from 50 at % to 80 at %.

The paraelectric layer may have the paraelectric property. The paraelectric layer may be formed of and/or include at least one of, for example, silicon oxide and/or high-k metal oxide materials. The metal oxide materials, which can be used as the paraelectric layer, may include at least one of, for example, hafnium oxide, zirconium oxide, and/or aluminum oxide, but the inventive concept is not limited to these examples.

The ferroelectric layer and the paraelectric layer may be formed of and/or include the same material. The ferroelectric layer may have the ferroelectric property, but the paraelectric layer may not have the ferroelectric property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric property only when its thickness is in a specific range. In an embodiment, the ferroelectric layer may have a thickness in the range of 0.5 to 10 nm, but the inventive concept is not limited to this example. Since a critical thickness associated with the occurrence of the ferroelectric property varies depending on the kind of the ferroelectric material, the thickness of the ferroelectric layer may be changed depending on the kind of the ferroelectric material.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

The first interlayer insulating layer 120 may be provided on the gate structure GST. The first interlayer insulating layer 120 may be provided on the gate structure GST and the inter-gate insulating layer 132. The first interlayer insulating layer 120 may include at least one of silicon oxide, silicon nitride, silicon oxynitride, or tetra ethyl ortho silicate (TEOS).

First active contacts AC1 and second active contacts AC2 may be provided on the first and second source/drain patterns SD1 and SD2, respectively. In the following description, an active contact is a contact that connects to a source/drain of an active fin region. Gate contacts GC may be provided on the gate structures GST. In the following description, a gate contact is a contact that connects to a gate structure GST. A contact, such as an active contact or a gate contact, may be referred to a long contact or as a short contact depending on their relative height. A long contact may be full height contact, and a short contact may be a reduced height contact. A reduced height contact is a contact that was initially a full height contact, but that subsequently had its height reduced in another process.

An interconnection layer M1 may be provided on the first interlayer insulating layer 120. The interconnection layer M1 may include an interconnection insulating layer 130 and an interconnection pattern M1_I. The interconnection pattern M1_I may include the first power line M1_R1, the second power line M1_R2, and the interconnection patterns M1_I. The interconnection lines M1_R1, M1_R2, and M1_I of the interconnection layer M1 may extend in the second direction D2 and be parallel to each other.

For example, the first and second power lines M1_R1 and M1_R2 may be respectively provided at the third and fourth borders BD3 and BD4 of the single height cell SHC. The first power line M1_R1 may extend along the third border BD3 in the second direction D2. The second power line M1_R2 may extend along the fourth border BD4 in the second direction D2.

The interconnection patterns M1_I of the interconnection layer M1 may be disposed between the first and second power lines M1_R1 and M1_R2. The interconnection patterns M1_I of the interconnection layer M1 may be arranged to be spaced apart from each other in the first direction D1 parallel to the substrate 100. The interconnection patterns M1_I may be line-shaped patterns that are extended in the second direction D2 crossing the first direction D1. A linewidth of each of the interconnection patterns M1_I may be less than a linewidth of each of the first and second power lines M1_R1 and M1_R2.

Referring back to FIGS. 4 and 5A to 5D, the first and second active contacts AC1 and AC2 may be provided to penetrate the inter-gate insulating layer 132 and the first interlayer insulating layer 120 and may be electrically connected to the first and second source/drain patterns SD1 and SD2, respectively. A pair of active contacts AC1 and AC2 may be respectively provided at opposite sides of the gate electrode GE. When viewed in a plan view, each of the active contacts AC1 and AC2 may be a bar-shaped pattern that is extended in the first direction D1.

The first active contact AC1 may be connected to the first source/drain pattern SD1. The first active contact AC1 may be a self-aligned contact. For example, the first active contact AC1 may be formed by a self-alignment process using the gate capping pattern GP and the gate spacer GS. For example, the first active contact AC1 may cover at least a portion of a side surface of the gate spacer GS. Although not shown, each of the active contacts AC1 and AC2 may cover a portion of a top surface of the gate capping pattern GP.

A metal-semiconductor compound layer SC (e.g., a silicide layer) may be interposed between the first active contact AC1 and the first source/drain pattern SD1 and between the second active contact AC2 and the second source/drain pattern SD2. The first and second active contacts AC1 and AC2 may be electrically connected to the source/drain patterns SD1 and SD2 through the metal-semiconductor compound layer SC. For example, the metal-semiconductor compound layer SC may be formed of and/or include at least one of titanium silicide, tantalum silicide, tungsten silicide, nickel silicide, or cobalt silicide.

The gate contacts GC may be provided to penetrate the inter-gate insulating layer 132 and the first interlayer insulating layer 120 and may be electrically connected to the gate electrodes GE, respectively. When viewed in a plan view, the gate contacts GC may overlap with the first and second active regions AR1 and AR2, respectively.

The first active contacts AC1 may include a first long active contact tAC1 and a first short active contact sAC1. The first long active contact tAC1 may be located at a position that is closer to the gate contact GC, compared with the position of the first short active contact sAC1. A length of the first long active contact tAC1 in the third direction D3 may be greater than a length of the first short active contact sAC1 in the third direction D3.

The first long active contact tAC1 may include a first long active conductive pattern tAFM1 and a first long active barrier pattern tABM1 enclosing the first long active conductive pattern tAFM1.

The first long active barrier pattern tABM1 may cover side and bottom surfaces of the first long active conductive pattern tAFM1. A level of a top surface tABM1TS of the first long active barrier pattern tABM1 may be equal to, or the same as a level of a top surface tAFM1TS of the first long active conductive pattern tAFM1. Here, the level may mean a distance measured from the substrate 100 in the third direction D3. For example, the expression “the levels are equal to each other” may mean that distances measured from the substrate 100 in the third direction D3 are equal to each other.

The first long active contact tAC1 may be connected to the interconnection pattern M1_I. A top surface of the first long active contact tAC1 may be in contact with the interconnection pattern M1_I. The top surface tAFM1TS of the first long active conductive pattern tAFM1 may be in contact with the interconnection pattern M1_I. The top surface tABM1TS of the first long active barrier pattern tABM1 may be in contact with the interconnection pattern M1_I. Since the first long active contact tAC1 is connected to the interconnection pattern M1_I, the first source/drain pattern SD1 and the interconnection pattern M1_I may be electrically connected to each other by the first long active contact tAC1.

The first short active contact sAC1 may include a first short active conductive pattern sAFM1 and a first short active barrier pattern sABM1 enclosing the first short active conductive pattern sAFM1. The first short active barrier pattern sABM1 may cover a portion of a side surface of the first short active conductive pattern sAFM1 and a bottom surface of the first short active conductive pattern sAFM1. The first short active barrier pattern sABM1 may be in contact with an upper insulating pattern UIP.

A level of a top surface sABM1TS of the first short active barrier pattern sABM1 may be lower than a level of the top surface tABM1TS of the first long active barrier pattern tABM1. The level of the top surface sABM1TS of the first short active barrier pattern sABM1 may be lower than a level of a top surface sAFM1TS of the first short active conductive pattern sAFM1. A level of the top surface sAFM1TS of the first short active conductive pattern sAFM1 may be lower than a level of the top surface tABM1TS of the first long active barrier pattern tABM1. Here, the level may mean a distance measured from the substrate 100 in the third direction D3. For example, the expression “a level of an element A is lower than a level of an element B” may mean that a distance of the element A from the substrate 100 in the third direction D3 is less than a distance of the element B.

The upper insulating pattern UIP may be provided on the first short active contact sAC1. The top surface sABM1TS of the first short active barrier pattern sABM1 and the top surface sAFM1TS of the first short active conductive pattern sAFM1 may be in contact with the upper insulating pattern UIP. The first short active contact sAC1 and the interconnection pattern M1_I may be spaced apart from each other by the upper insulating pattern UIP. The first short active contact sAC1 and the interconnection pattern M1_I may be electrically separated from each other by the upper insulating pattern UIP.

Each of the first long active conductive pattern tAFM1 and the first short active conductive pattern sAFM1 may be formed of and/or include at least one metallic material (e.g., aluminum, copper, tungsten, molybdenum, and cobalt).

Each of the first long active barrier pattern tABM1 and the first short active barrier pattern sABM1 may include a metal layer or a metal nitride layer. The metal layer may be formed of and/or include at least one of titanium, tantalum, tungsten, nickel, cobalt, or platinum. The metal nitride layer may be formed of and/or include at least one of titanium nitride (TiN), tantalum nitride (TaN), tungsten nitride (WN), nickel nitride (NiN), cobalt nitride (CoN), or platinum nitride (PtN).

The gate contact GC may include a long gate contact tGC and a short gate contact sGC. A bottom surface of the long gate contact tGC may be connected to the gate electrode GE, and a top surface of the long gate contact tGC may be in contact with the interconnection pattern M1_I. A bottom surface of the short gate contact sGC may be connected to the gate electrode GE, and a top surface of the short gate contact sGC may be spaced apart from the interconnection pattern M1_I and may be in contact with the upper insulating pattern UIP.

The long gate contact tGC may include a long gate conductive pattern tGFM and a long gate barrier pattern tGBM enclosing the long gate conductive pattern tGFM. The short gate contact sGC may include a short gate conductive pattern sGFM and a short gate barrier pattern sGBM enclosing the short gate conductive pattern sGFM. A region on the short gate contact sGC may be filled with the upper insulating pattern UIP.

The top surface of the long gate contact tGC may be in contact with the interconnection pattern M1_I. A top surface tGFMTS of the long gate conductive pattern tGFM may be in contact with the interconnection pattern M1_I. A top surface tGBMTS of the long gate barrier pattern tGBM may be in contact with the interconnection pattern M1_I.

The top surface of the short gate contact sGC and the interconnection pattern M1_I may be spaced apart from each other. A top surface sGFMTS of the short gate conductive pattern sGFM and the interconnection pattern M1_I may be spaced apart from each other. A top surface sGBMTS of the short gate barrier pattern sGBM and the interconnection pattern M1_I may be spaced apart from each other.

A level of a top surface of the short gate conductive pattern sGFM may be equal to or the same as a level of a top surface of a short active conductive pattern sAFM.

A level of the top surface of the short gate contact sGC may be lower than a level of the top surface of the long gate contact tGC. A level of the top surface sGFMTS of the short gate conductive pattern sGFM may be lower than a level of the top surface tGFMTS of the long gate conductive pattern tGFM. A level of the top surface sGBMTS of the short gate barrier pattern sGBM may be lower than a level of the top surface tGBMTS of the long gate barrier pattern tGBM. The level of the top surface sGBMTS of the short gate barrier pattern sGBM may be lower than the level of the top surface sGFMTS of the short gate conductive pattern sGFM.

An upper portion of the first short active contact sAC1 adjacent to the long gate contact tGC may be filled with the upper insulating pattern UIP. For example, the upper portion of the first short active contact sAC1, which is adjacent to the long gate contact tGC, may not overlap with the long gate contact tGC horizontally (i.e., the first and second directions D1 and D2) by the upper insulating pattern UIP. Thus, it may be possible to prevent the long gate contact tGC and the first short active contact sAC1, which are adjacent to each other, from being in contact with each other and prevent a short circuit from occurring therebetween.

The second active contact AC2 may be connected to the second source/drain pattern SD2. The second active contact AC2 may be provided to have the same or substantially the same features as the first active contact AC1.

FIG. 5E is a sectional view illustrating a semiconductor device according to an embodiment of the inventive concept and corresponding to the line C-C′ of FIG. 4. For concise description, a previously described element may be identified by the same reference number without repeating an overlapping description thereof.

Referring to FIG. 5E, the gate contact GC may include the long gate contact tGC and the short gate contact sGC. The short gate contact sGC may include the short gate conductive pattern sGFMa and the short gate barrier pattern sGBMa.

The short gate conductive pattern sGFMa may have a partially-recessed shape. For example, the short gate conductive pattern sGFMa may be provided to have a stepwise shape with a partially-recessed region. In this case, a level of the uppermost surface sGFMaT1 of the short gate conductive pattern sGFMa may be higher than a level of the lowermost surface sGFMaT2 of the short gate conductive pattern sGFMa. In this case, the uppermost surface sGFMaT1 of the short gate conductive pattern sGFMa may be defined as the highest portion of the top surface of the short gate conductive pattern sGFMa. The lowermost surface sGFMaT2 of the short gate conductive pattern sGFMa may be defined as the lowest portion of the top surface of the short gate conductive pattern sGFMa.

A portion of the short gate conductive pattern sGFMa, which overlaps with the interconnection pattern M1_I vertically (e.g., in the third direction D3), may be recessed. A portion of the short gate conductive pattern sGFMa, which does not overlap with the interconnection pattern M1_I vertically (e.g., in the third direction D3), may not be recessed.

The recessed portion of the short gate conductive pattern sGFMa may be filled with the upper insulating pattern UIP. The lowermost surface sGFMaT2 of the short gate conductive pattern sGFMa may be in contact with the upper insulating pattern UIP. The uppermost surface sGFMaT1 of the short gate conductive pattern sGFMa may be in contact with the interconnection insulating layer 130.

The short gate barrier pattern sGBMa may be in contact with a side surface of the short gate conductive pattern sGFMa. The surface of the short gate barrier pattern sGBMa in contact with the recessed portion of the short gate conductive pattern sGFMa may be provided at a level lower than the surface of the short gate barrier pattern sGBMa in contact with the non-recessed portion of the short gate conductive pattern sGFMa. The short gate barrier pattern sGBMa may have side surfaces that are located at different levels.

In an embodiment, the surface of the short gate barrier pattern sGBMa that is in contact with the recessed portion of the short gate conductive pattern sGFMa may be provided at the same level as the lowermost surface sGFMaT2 of the short gate conductive pattern sGFMa.

In an embodiment, although not shown, the surface of the short gate barrier pattern sGBMa that is in contact with the recessed portion of the short gate conductive pattern sGFMa may be provided to a level lower than the lowermost surface sGFMaT2 of the short gate conductive pattern sGFMa.

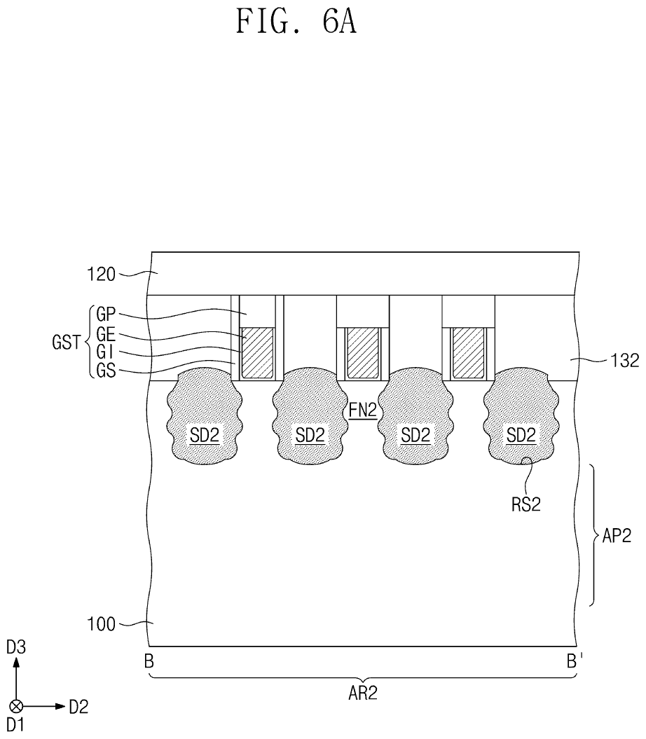

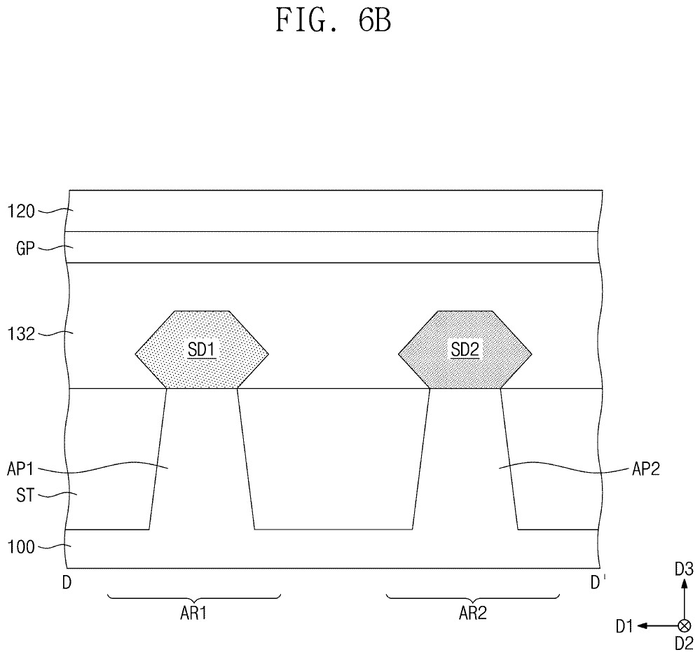

FIGS. 6A to 11A are sectional views, which are taken along the line B-B′ of FIG. 4 to illustrate a method of fabricating a semiconductor device, according to an embodiment of the inventive concept. FIGS. 6B to 11B are sectional views, which are taken along the line D-D′ of FIG. 4 to illustrate a method of fabricating a semiconductor device according to an embodiment of the inventive concept. To avoid a duplicative description, a previously described element may be identified by the same reference number without repeating the description thereof with the understanding that the previous description is applicable to the element.

Referring to FIGS. 6A and 6B, the substrate 100 including the first and second active patterns AP1 and AP2 may be provided. The first and second active patterns AP1 and AP2 may be formed on the substrate 100. For example, the substrate 100 may be etched to form trenches with the area between the trenches forming the active patterns, the active patterns may be epitaxially grown from the substrate 100, or a combination of removing material from the substrate 100 and growing the active patterns from the substrate may be performed. The device isolation layer ST may be formed on the substrate 100 to define the active fin regions. For example, the device isolation layer ST may be formed as part of a deposition process. The gate structures GST, each of which includes the gate insulating layer GI, the gate electrode GE, the gate capping pattern GP, and the gate spacer GS, may be formed on the substrate 100 and on the active fin regions. For example, the gate structures GST may be formed through deposition of material layers of the gate insulating layer GI, the gate electrode GE, the gate capping pattern GP, patterning the same (e.g., with a selective etching process) and forming gate spacers on either side of this patterned structure (e.g., by depositing the material layer of the gate spacer and etching the same).

The first source/drain pattern SD1 may be formed on the first active region AR1 of the substrate 100. The second source/drain pattern SD2 may be formed on the second active region AR2 of the substrate 100. For example, the source/drain patterns may be formed by implanting impurities into areas of the active regions between the gate structures.

The inter-gate insulating layer 132 may be formed between the gate structures GST, which are spaced apart from each other, to cover the first and second source/drain patterns SD1 and SD2. For example, the inter-gate insulating layer 132 may be formed as part of a deposition process. The first interlayer insulating layer 120 may be formed on the inter-gate insulating layer 132 and on the gate capping pattern GP of the gate structure GST. For example, the first interlayer insulating layer 120 may be formed as part of a deposition process.

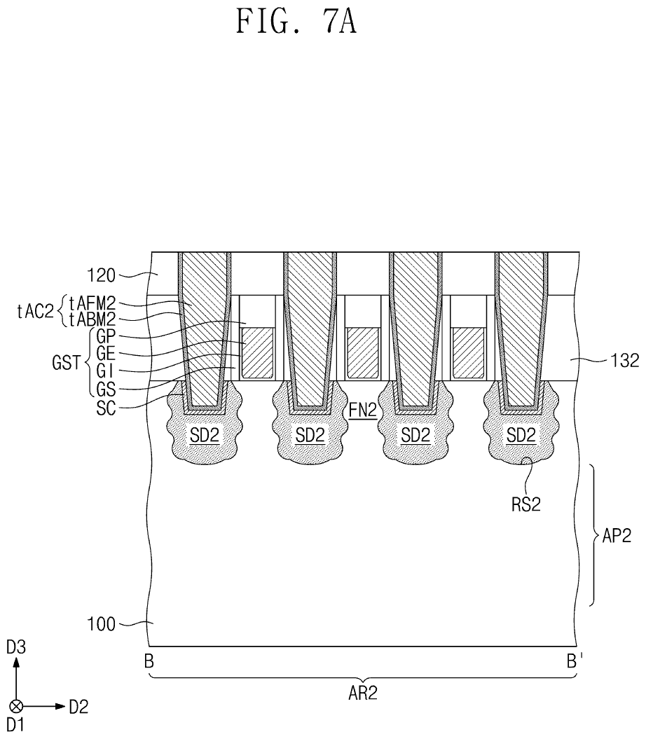

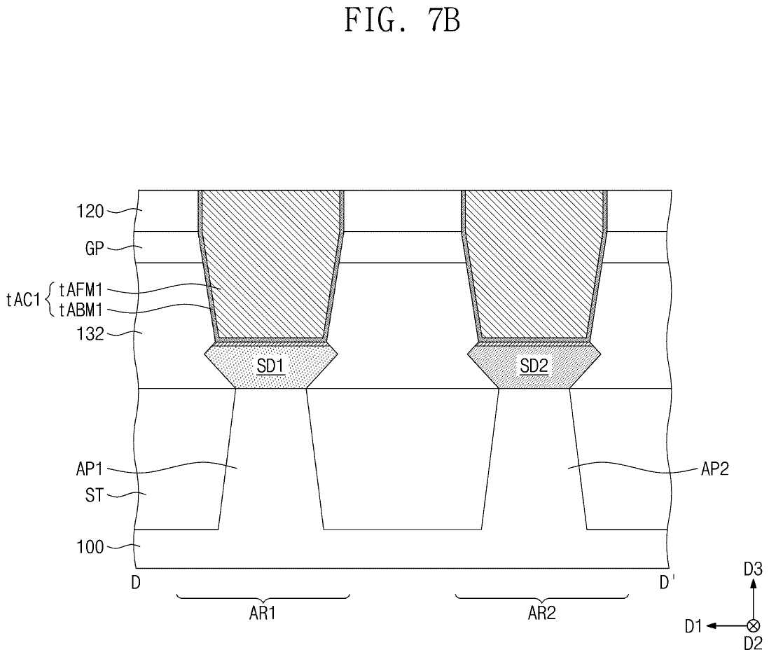

Referring to FIGS. 7A and 7B, the first long active contact tAC1 may be formed to penetrate the first interlayer insulating layer 120, the gate capping pattern GP, and the inter-gate insulating layer 132 and may be connected to the first source/drain pattern SD1. A second long active contact tAC2, which is connected to the second source/drain pattern SD2, may be formed to have a structure similar to the first long active contact tAC1.

The formation of the first long active contact tAC1 may include forming the first long active barrier pattern tABM1 and forming the first long active conductive pattern tAFM1 on the first long active barrier pattern tABM1.

For example, a long active contact mask (not shown) may be formed on the first interlayer insulating layer 120, and then, a long active contact hole (not shown) may be formed to penetrate the first interlayer insulating layer 120, the gate capping pattern GP, the inter-gate insulating layer 132, and a portion of the first source/drain pattern SD1 using the long active contact mask (not shown) as a mask. The long active contact hole (not shown) may be formed to expose the first source/drain pattern SD1. For example, an etching process may remove portions of the first interlayer insulating layer 120, the gate capping pattern GP, the inter-gate insulating layer 132, and a portion of the first source/drain pattern SD1). The metal-semiconductor compound layer SC may be formed on the exposed first source/drain pattern SD1 and along the long active contact hole (not shown). For example, a deposition process may form the metal-semiconductor compound layer SC. The first long active barrier pattern tABM1 may be formed on the metal-semiconductor compound layer SC and in the long active contact hole (not shown), and the first long active conductive pattern tAFM1 may be formed on the first long active barrier pattern tABM1 to fill a remaining portion of the long active contact hole. For example, the first long active barrier pattern tABM1 and the first long active conductive pattern tAFM1 may be formed in separate deposition processes.

The first long active contact tAC1 may be connected to the first source/drain pattern SD1. An upper portion of the first long active contact tAC1 and the long active contact mask (not shown) may be removed. A planarization process may be performed in such a way that a top surface of the first interlayer insulating layer 120 and a top surface of the first long active contact tAC1 are exposed, and in such a way that a top surface of the first interlayer insulating layer 120 and a top surface of the first long active contact tAC1 are at the same or substantially the same level. In the present specification, the term ‘substantially the same’ may mean that the difference falls within a margin of error of approximately 5%.

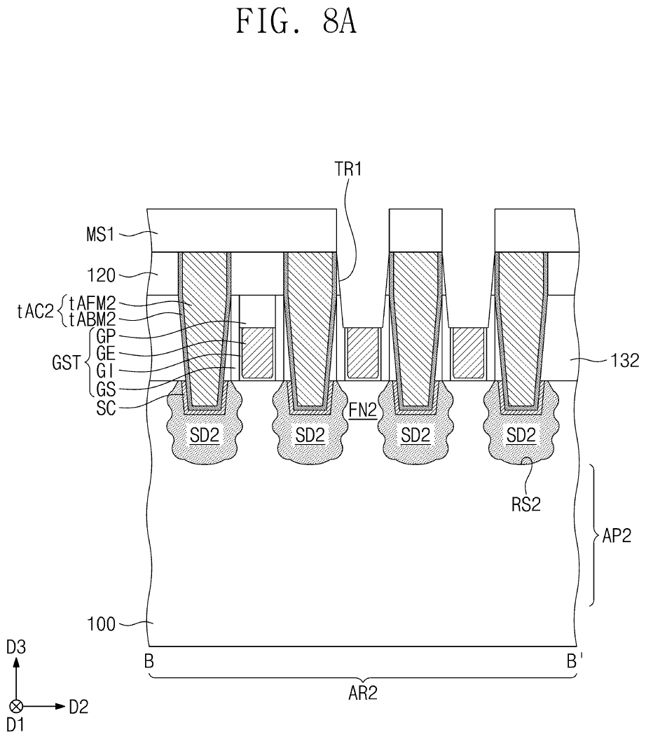

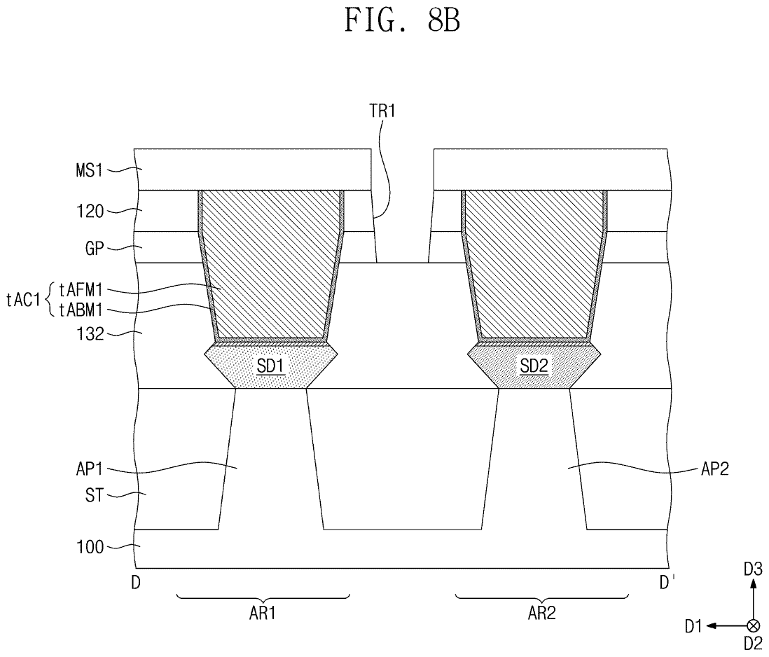

Referring to FIGS. 8A and 8B, a gate mask pattern MS1 may be formed on top surfaces of the first interlayer insulating layer 120 and the first long active contact tAC1. The gate mask pattern MS1 may be formed to cover the top surface of the first long active contact tAC1 and to pattern a region, on which the gate contact GC will be formed. A first trench TR1 may be formed by patterning the region on which the gate contact GC will be formed using the gate mask pattern MS1. The first trench TR1 may be formed to penetrate the first interlayer insulating layer 120 and the gate capping pattern GP. The first trench TR1 may be formed to expose the inter-gate insulating layer 132. The first trench TR1 may be formed to penetrate a portion of the gate structure GST. Portions of the top surface of the gate electrode GE, the top surface of the gate insulating layer GI, and the top surface of the gate spacer GS may be exposed by the first trench TR1. For example, an etching process may remove material to form the first trench TR1.

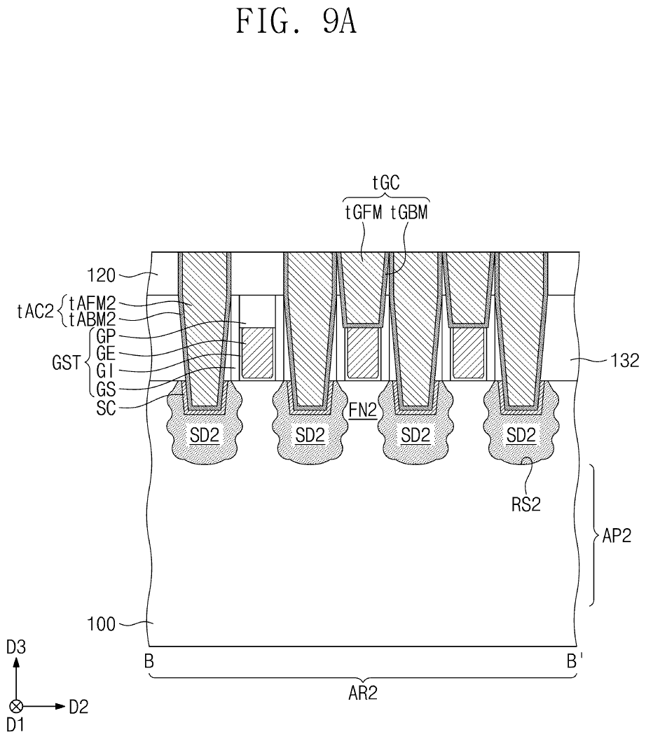

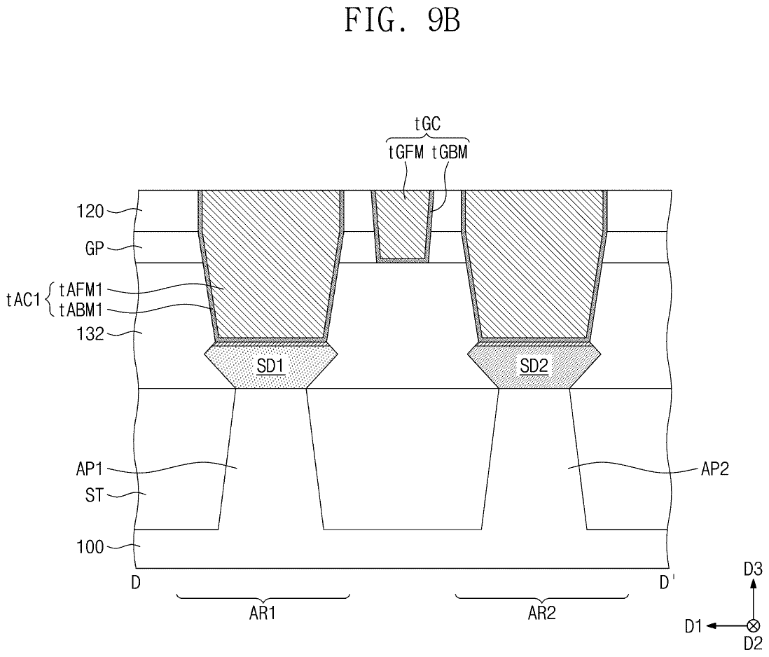

Referring to FIGS. 9A and 9B, the long gate contact tGC may be formed in the first trench TR1. The long gate contact tGC may be connected to the gate structure GST. The long gate barrier pattern tGBM may be formed in and along the first trench TR1, and the long gate conductive pattern tGFM may be formed on the long gate barrier pattern tGBM. For example, the long gate barrier pattern tGBM and the long gate conductive pattern tGFM may be formed in separate deposition processes. The gate mask pattern MS1 may be removed. The top surface of the long gate contact tGC, the top surface of the first interlayer insulating layer 120, and the top surface of the first long active contact tAC1 may be simultaneously planarized and may be exposed (e.g., may be planarized in the same process).

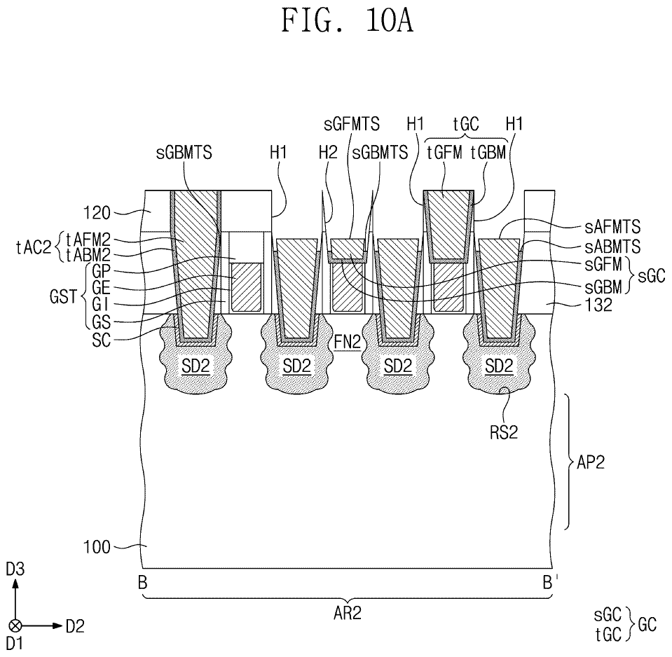

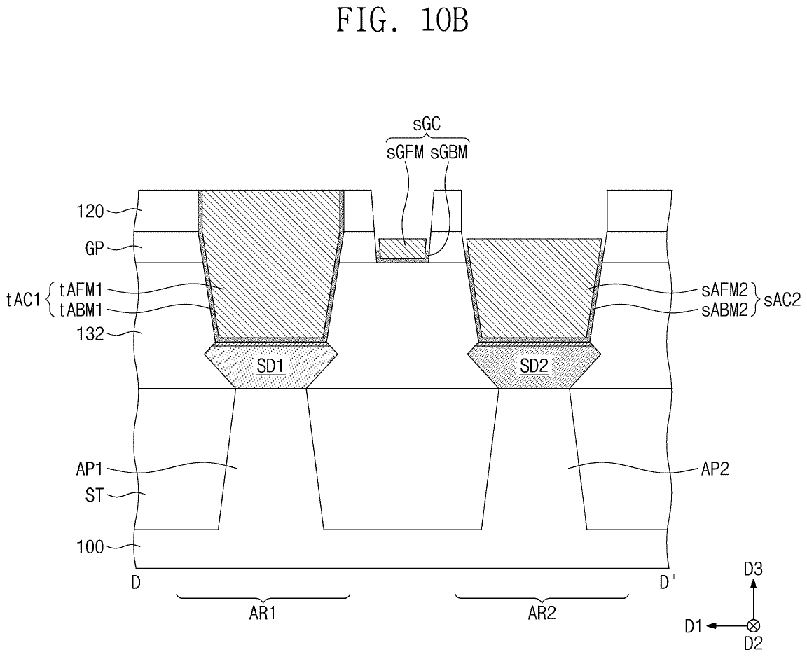

Referring to FIGS. 10A and 10B, some of the first long active contacts tAC1 may be recessed to form the first short active contacts sAC1 (e.g., a subset of the first long active contacts tAC1). Some of the long gate contacts tGC may be recessed by an etching process to form the short gate contacts sGC (e.g., a subset of the long gate contacts tGC). The recessing of the first long active contacts tAC1 and the recessing of the long gate contacts tGC may be performed at the same time in the same etching process (e.g., in situ in the same chamber without a vacuum break to the chamber). For example, the first short active contacts sAC1 and the short gate contacts sGC may be formed at the same time and part of the same process.

The formation of the first short active contact sAC1 and the short gate contact sGC may include simultaneously removing a portion of the first long active conductive pattern tAFM1 and a portion of the long gate conductive pattern tGFM to form the first short active conductive pattern sAFM1 and the short gate conductive pattern sGFM, respectively. For example, an etching process may remove both a portion of the first long active conductive pattern tAFM1 and a portion of the long gate conductive pattern tGFM.

The formation of the first short active contact sAC1 and the short gate contact sGC may include simultaneously removing a portion of the first long active barrier pattern tABM1 and a portion of the long gate barrier pattern tGBM to form the first short active barrier pattern sABM1 and the short gate barrier pattern sGBM, respectively.

The removal depth of the first long active barrier pattern tABM1 may be larger than the removal depth of the first long active conductive pattern tAFM1. Thus, the level of the top surface sABM1TS of the first short active barrier pattern sABM1 may be lower than the level of the top surface sAFM1TS of the first short active conductive pattern sAFM1.

The uppermost surface of the first short active contact sAC1 may be the top surface sAFM1TS of the first short active conductive pattern sAFM1. In this case, a level of the uppermost surface of the first short active contact sAC1 may be higher than a level of the uppermost surface of the first short active barrier pattern sABM1.

The removal depth of the long gate barrier pattern tGBM may be larger than the removal depth of the long gate conductive pattern tGFM. Thus, the level of the top surface sGBMTS of the short gate barrier pattern sGBM may be lower than the level of the top surface sGFMTS of the short gate conductive pattern sGFM.

For example, a mask pattern (not shown) may be formed on the planarized top surfaces of the first interlayer insulating layer 120, the first long active contact tAC1, and the long gate contact tGC. The mask pattern (not shown) may be patterned to expose a region, in which the first short active contacts sAC1 and the short gate contacts sGC are formed.

Some of the first long active contacts tAC1 exposed by the mask pattern (not shown) may be recessed to form the first short active contacts sAC1 (e.g., a subset of the first long active contacts tAC1 recessed in an etching process). Upper portions of the exposed first short active contacts sAC1 may be defined as a first hole H1. The first hole H1 may be defined by the first short active contacts sAC1 and the first interlayer insulating layer 120.

Some of the long gate contacts tGC exposed by the mask pattern (not shown) may also be recessed, when some of the first long active contact tAC1 exposed by the mask pattern (not shown) are recessed. That is, the recessing of the first long active contacts tAC1 and the recessing of the long gate contacts tGC may be performed through a single process such as an etching process.

Some of the long gate contacts tGC exposed by the mask pattern (not shown) may be recessed to form the short gate contacts sGC (e.g., a subset of the long gate contacts tGC). Upper portions of the exposed short gate contacts sGC may be defined as a second hole H2. The second hole H2 may be defined by the short gate contacts sGC and the first interlayer insulating layer 120.

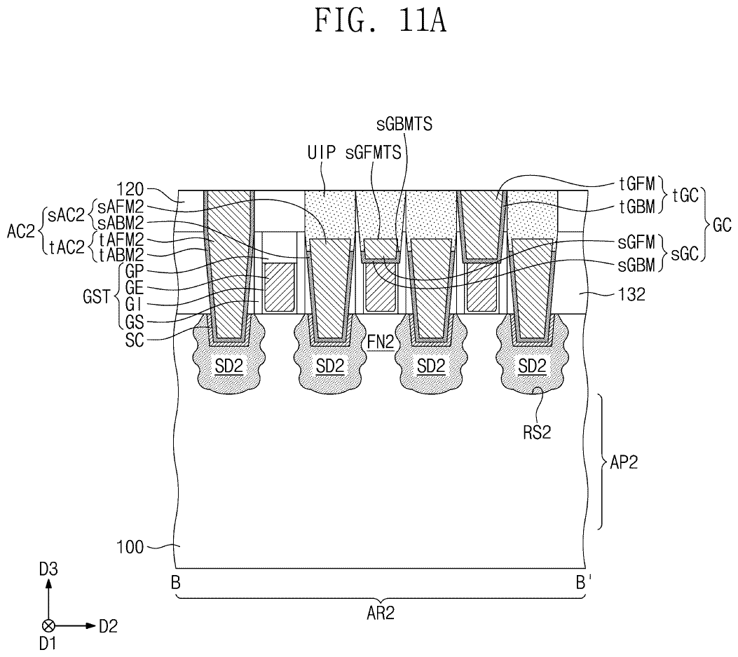

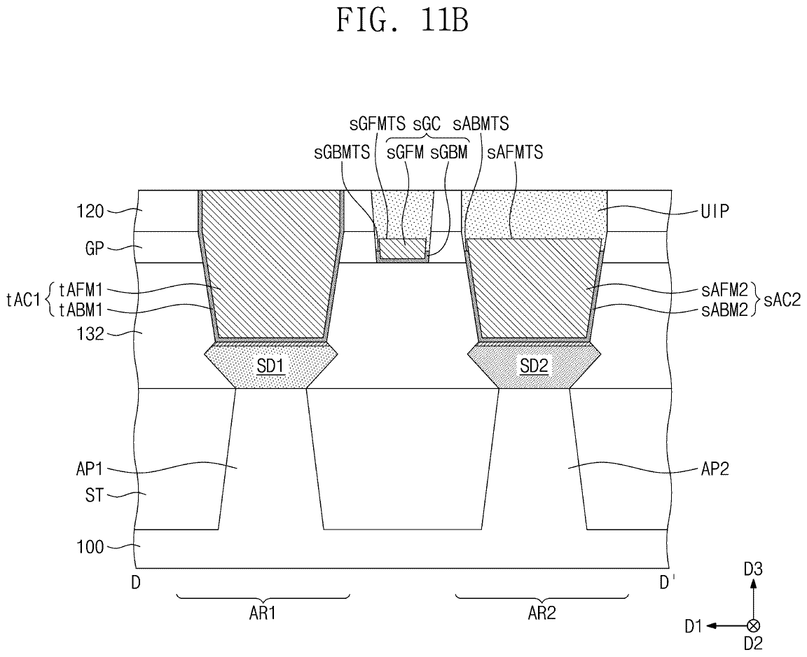

Referring to FIGS. 11A and 11B, the upper insulating pattern UIP may be formed to fill the first hole H1 and the second hole H2. The upper insulating pattern UIP may be formed on the first short active contact sAC1 and the short gate contact sGC. For example, a deposition process may form the upper insulating pattern UIP.

The upper insulating pattern UIP, the top surface of the first long active contact tAC1, the top surface of the first interlayer insulating layer 120, and the long gate contact tGC may be planarized at the same time (e.g., as part of the same planarization process).

Referring back to FIGS. 4 and 5A to 5D, the interconnection layer M1 may be formed on the first long active contact tAC1, the long gate contact tGC, the first interlayer insulating layer 120, and the upper insulating pattern UIP.

The formation of the interconnection layer M1 may include forming the interconnection insulating layer 130 on the first long active contact tAC1, the long gate contact tGC, the first interlayer insulating layer 120, and the upper insulating pattern UIP. The interconnection layer M1 may be formed by a deposition process. The interconnection layer M1 may be formed directly on the first long active contact tAC1 and the long gate contact tGC.

The formation of the interconnection layer M1 may include forming the interconnection pattern M1_I through a mask patterning process, after the formation of the interconnection insulating layer 130. The interconnection pattern M1_I may be formed to be in contact with the first long active contact tAC1 and the long gate contact tGC. The first power line M1_R1 and the second power line M1_R2 may be formed. For example, the interconnection pattern M1_1 may be formed by a deposition process.

The semiconductor device may be fabricated to have the same structure as that in FIGS. 4 and 5A to 5D.

In a three-dimensional field effect transistor according to an embodiment of the inventive concept, a long active contact, a short active contact, a long gate contact, and a short gate contact may be formed at the same time (e.g., as part of the same processes). The long active contact and the long gate contact may be connected to an interconnection pattern and without the use of a via plug. Accordingly, it may be possible to improve a short failure between the active contact and the gate contact, and by skipping a via layer scheme, it may be possible to simplify a fabrication process. It may be possible to improve the electrical and reliability characteristics of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A method of fabricating a semiconductor device, comprising:
providing a substrate;
forming active fin regions, source/drain patterns, gate structures, and an inter-gate insulating layer on the substrate;
forming full height contacts penetrating through the inter-gate insulating layer that are respectively connected to the source/drain patterns;
forming full height gate contacts respectively connected to the gate structures;
simultaneously recessing a first subset of the full height contacts and a second subset of the full height gate contacts to form reduced height contacts and reduced height gate contacts, respectively;
forming an upper insulating pattern on the reduced height contacts and the reduced height gate contacts; and
forming interconnection patterns on the full height contacts, the full height gate contacts, and the upper insulating pattern.

2. The method of claim 1, wherein
each of the full height contacts comprises a full height barrier pattern,
each of the full height gate contacts comprises a full height gate barrier pattern,
each of the reduced height contacts comprises a reduced height barrier pattern,
each of the reduced height gate contacts comprises a reduced height gate barrier pattern, and
forming the reduced height barrier patterns and the reduced height gate barrier patterns comprises removing a portion of the full height barrier patterns and a portion of the full height gate barrier pattern, simultaneously.

3. The method of claim 1, wherein
each of the reduced height gate contacts comprises a reduced height gate conductive pattern and a reduced height gate barrier pattern,
each of the reduced height contacts comprises a reduced height conductive pattern and a reduced height barrier pattern, and
a level of a top surface of the reduced height gate conductive patterns is the same as a level of a top surface of the reduced height conductive patterns.

4. The method of claim 1, wherein
each of the reduced height gate contact comprises a reduced height gate conductive pattern and a reduced height gate barrier pattern, and
a level of a top surface of the reduced height gate barrier patterns is lower than a level of a top surface of the reduced height gate conductive patterns.

5. The method of claim 1, wherein each of the full height contacts and the full height gate contacts are in contact with corresponding interconnection patterns, and
the reduced height contacts and the reduced height gate contacts are spaced apart from the interconnection patterns.

6. The method of claim 1, wherein
each of the full height contacts comprises a full height conductive pattern and a full height barrier pattern,
each of the reduced height contacts comprises a reduced height conductive pattern and a reduced height barrier pattern,
a level of a top surface of the full height conductive patterns is the same as a level of a top surface of the full height barrier patterns, and
a level of a top surface of the reduced height barrier patterns is lower than a level of a top surface of the reduced height conductive patterns.

7. The method of claim 1, further comprising, before the forming of the full height contacts, forming a metal-semiconductor compound layer on the source/drain patterns,
wherein the metal-semiconductor compound layer is interposed between the source/drain patterns and the full and reduced height contacts.

8. The method of claim 1, wherein the forming of the interconnection patterns comprises forming the interconnection patterns spaced apart from each other in a first direction parallel to the substrate and having a line shape extending in a second direction crossing the first direction.

9. A method of fabricating a semiconductor device, comprising:
providing a substrate;
forming active fin regions, source/drain patterns, gate structures, and an inter-gate insulating layer on the substrate;
forming full height contacts penetrating through the inter-gate insulating layer and respectively connected to the source/drain patterns, the full height contacts each comprising a corresponding full height barrier pattern;
forming full height gate contacts respectively connected to the gate structures, the full height gate contacts each including a full height gate barrier pattern;
simultaneously recessing a first subset of the full height contacts and a second subset of the full height gate contacts to form reduced height contacts and reduced height gate contacts, respectively; and
forming an upper insulating pattern on the reduced height contacts and the reduced height gate contacts,
wherein the forming of the reduced height contacts and the reduced height gate contacts comprises removing a portion of the full height barrier patterns of the first subset of full height contacts and a portion of the full height gate barrier patterns of the second subset of the full height gate contacts simultaneously.

10. The method of claim 9, further comprising forming interconnection patterns on the full height contacts, the full height gate contacts, and the upper insulating pattern.

11. The method of claim 10, wherein the forming of the interconnection patterns comprises forming the interconnection patterns spaced apart from each other in a first direction parallel to the substrate and having a line shape extending in a second direction crossing the first direction.

12. The method of claim 10, wherein the upper insulating pattern is interposed between the reduced height contacts and the interconnection patterns and between the reduced height gate contacts and the interconnection patterns.

13. The method of claim 9, wherein the removing of the portion of the full height barrier patterns and the portion of the full height gate barrier patterns is performed to form a reduced height barrier patterns and a reduced height gate barrier patterns, respectively, and
a level of the uppermost surface of the reduced height contacts is higher than a level of the uppermost surface of the reduced height barrier patterns.

14. The method of claim 9, wherein
each of the full height contacts comprises a full height conductive pattern,
each of the full height gate contacts comprises a full height gate conductive pattern, and
the forming of the reduced height contacts and the reduced height gate contacts comprises simultaneously removing a portion of the full height conductive pattern and a portion of the full height gate conductive pattern to form a reduced height conductive pattern and a reduced height gate conductive pattern, respectively.

15. The method of claim 9, further comprising, before the forming of the full height contacts, forming a metal-semiconductor compound layer on the source/drain patterns,
wherein the metal-semiconductor compound layer is interposed between the source/drain patterns and the full and reduced height contacts.

16. The method of claim 9, further comprising:
performing a planarization process to expose a top surface of the full height contacts, a top surface of the full height gate contacts, and a top surface of the upper insulating pattern; and
forming interconnection patterns on the exposed top surfaces of the full height contacts, the full height gate contacts, and the upper insulating pattern.

17. The method of claim 9, further comprising forming interconnection patterns on the upper insulating pattern,
wherein each of the interconnection patterns are electrically connected to a corresponding full height contact and a corresponding full height gate contact, and
the interconnection patterns are spaced apart from the reduced height contacts and the reduced height gate contacts.

18. A method of fabricating a semiconductor device, comprising:
providing a substrate;
forming active fin regions on the substrate, the active fin regions include first and second active fin regions;
forming gate structures on the active fin regions;
forming first source/drain patterns and second source/drain patterns on the first and second active fin regions of the substrate, respectively;
forming an inter-gate insulating layer to cover the first source/drain patterns and the second source/drain patterns;
forming full height contacts respectively connected to the first source/drain patterns and penetrating through the inter-gate insulating layer;
forming full height gate contacts respectively connected to the gate structures;
recessing a first subset of the full height contacts to form reduced height contacts;
recessing a second subset of the full height gate contacts to form reduced height gate contacts;
forming an upper insulating pattern on the reduced height contacts and the reduced height gate contacts; and
forming interconnection patterns on the full height contacts, the full height gate contacts, and the upper insulating patterns,
wherein the recessing of the full height contacts and the recessing of the full height gate contacts are performed simultaneously, and
the forming of the interconnection patterns comprises forming the interconnection patterns spaced apart from each other in a first direction parallel to the substrate and having a line shape extending in a second direction crossing the first direction.

19. The method of claim 18, further comprising, before the forming of the full height contacts, forming a metal-semiconductor compound layer on the source/drain patterns,
wherein the metal-semiconductor compound layer is interposed between the source/drain patterns and the full and reduced height contacts.

20. The method of claim 19, further comprising performing a planarization process to expose a top surface of the full height contacts, a top surface of the full height gate contacts, and a top surface of the upper insulating pattern, before the forming of the interconnection patterns.
